(19) United States
(12) Patent Application Publication
(10) Pub. No.: US 2004/0245571 A1
(43) Pub. Date: Dec. 9, 2004

(54) Semiconductor-on-insulator article and method of making same

(76) Inventors: Zhiyuan Cheng, Cambridge, MA (US); Eugene A. Fitzgerald, Windham, NH (US)

Correspondence Address: Gauthier & Connors LLP, Suite 3300, 225 Franklin Street, Boston, MA, 02110, US

(21) Appl. No.: 10/778,966

(22) Filed: Feb. 13, 2004

Related U.S. Application Data
(60) Provisional application No. 60/447,192, filed on Feb. 13, 2003.

(51) Int. Cl. H01L 27/01

(52) U.S. Cl. 257/347

(57) ABSTRACT

A semiconductor structure includes a substrate. A first semiconductor layer is formed on the substrate and being converted into a porous layer. The porous layer is further oxidized to form a buried oxide layer.

### PRIORITY INFORMATION

This application claims priority from provisional application Ser. No. 60/447,192 filed Feb. 13, 2003, which is incorporated herein by reference in its entirety.

### BACKGROUND OF THE INVENTION

The invention relates to the field of semiconductor fabrication, and in particular to a technique of producing a semiconductor substrate of silicon-on-insulator (SOI), relaxed Si₁₋ₓGeₓ-on-insulator (SGOI), strained-Si-on-insulator (SSOI) substrate without using a costly process such as high dose ion (oxygen or hydrogen) implantation and wafer bonding.

The advantages of silicon-on-insulator (SOI) technology have been demonstrated for commercial ICs. There are several methods for SOI wafer fabrication: SIMOX (separation by implantation of oxygen), BESOI (bonded and etch back SOI), UNIBOND (bonded and separated by H-induced delamination), ELTRAN (Epitaxial Layer transfer), etc. As an example, the typical process of the ELTRAN method is as follows: starting with a Si substrate, the top Si layer is converted into a porous Si layer. The porous Si material still keeps the single-crystalline structure of the Si material. Therefore, a second single-crystalline continuous Si film can be epitaxially deposited on the surface of this porous Si material. The structure is subsequently bonded to an insulating Si wafer by wafer bonding. The bonded pair is then split at the porous Si layer, leaving the second Si film on the handle wafer, resulting in a SOI substrate.

Similar methods are also used to produce relaxed-SiGe-on-insulator (SGOI), strained-SGOI, strained-Si-on-insulator (SSOD, relaxed-Ge-on-insulator (GeOI), or strained-GeOI substrates. SGOI, SSOI, and GeOI technology combines the advantages of both SOI technology and strained-Si, Ge and SiGe technology. Strained-Si, Ge and SiGe technology enhances device performance dramatically, including enhanced electron and hole mobility.

However, those methods involve the process of high dose oxygen or hydrogen implantation or wafer bonding, which is very costly. It is also difficult to produce SOI wafers with very thin semiconductor film and with very good thickness uniformity. A simpler method with low production cost and with improved film thickness uniformity is desired. Ultra-thin SOI wafer with high film thickness uniformity is required for modern small dimension device fabrication.

In the prior art, porous Si (PS) has been used to fabricated SOI structure, but only as a sacrificial layer, and porous Si material is not present in the final SOI structure. The ELTRAN method described above is one such case. Another such case in the prior art is reported as a full isolation by oxidized porous silicon technique (FIPOS), as in reference: K Imai, and H. Unno, IEEE Trans Electron Devices, 1984, Vol 31, pp. 297-302. The typical process of FIPOS is: form two films on a Si substrate; open some windows on the top film to explore the surface of the buried film; using the windows, convert the buried film into porous Si; and then oxidize the porous Si into oxide layer. The advantage of the method is that there in no costly wafer-bonding step. A drawback of this method is its limitation to localized SOI islands only.

Porous Si is typically formed by electrochemical processes, such as a anodization process or a stain etch process. In the anodization method, by adjusting the anodization current and other conditions, various porosity and pore size can be achieved, producing different porous Si which are classified into 3 categories in the prior art: the miroporous (pore size less than 2 nm), the mesoporous (pore size between 2 nm and 50 nm) and the macroporous (pore size large than 50 nm).

### SUMMARY OF THE INVENTION

According to one aspect of the invention, there is provided a semiconductor on porous structure that includes a substrate. A first semiconductor layer is formed on the substrate. The first semiconductor layer is converted into a porous semiconductor layer a second semiconductor layer is formed on the first semiconductor layer.

According to another aspect of the invention, there is provided a semiconductor structure that includes a substrate. A porous semiconductor layer is formed on the substrate. An insulating film is formed on the porous layer. A second semiconductor layer is formed on the insulating film.

According to another aspect of the invention, there is provided a semiconductor structure that includes a substrate. A first semiconductor layer is formed on the substrate and being converted into a porous layer. The porous layer is further oxidized to form a buried oxide layer.

According to another aspect of the invention, there is provided method of forming a semiconductor structure. The method includes providing a substrate and forming a first semiconductor layer on the substrate. The first semiconductor layer is converted into a porous layer. Furthermore, the method includes oxidizing or nitridizing the porous layer to form a buried oxide layer.

According to another aspect of the invention, there is provided method of forming a semiconductor structure. The method includes providing a substrate and forming a porous semiconductor layer on the substrate. An insulating film is formed on the porous layer. Furthermore, the method includes forming a second semiconductor layer on the insulating film.

According to another aspect of the invention, there is provided method of forming a semiconductor on porous structure. The method includes providing a substrate and forming a first semiconductor layer on the substrate. The first semiconductor layer is converted into a porous semiconductor layer. A second semiconductor layer is formed on the first semiconductor layer.

### BRIEF DESCRIPTION OF THE DRAWINGS

FIG. 1A is schematic block diagram illustrating a Si-on-porous structure; FIG. 1B is a schematic diagram illustrating conventional semiconductor devices being formed on the Si-on-porous structure; FIG. 1C is a schematic diagram illustrating the potential of a Si-on-porous structure being integrated with different types of devices, all within a single monolithic Si substrate;

FIGS. 2A-2C are schematic block diagrams illustrating another embodiment of the semiconductor-on-insulator-on-porous structure;

FIGS. 3A-3C are schematic block diagrams illustrating a simple technique to produce a Si-on-porous structure with low fabrication cost and high film uniformity;

FIGS. 4A-4D are schematic block diagrams illustrating a simple technique to produce a Si-on-insulator-on-porous structure with low fabrication cost and high film uniformity

FIGS. 5A-5C are schematic block diagrams illustrating a another simple technique to produce a Si-on-insulator-on-porous structure with a ZrO₂ layer;

FIGS. 6A-6F are schematic block diagrams illustrating an approach to fabricating a SOI structure;

FIGS. 7A-7D are schematic block diagrams illustrating an approach to fabricating a SOI structure by blocking the diffusion of oxidants from the side of a wafer;

FIG. 8 is a schematic block diagram illustrating an oxidation mask layer being added on top of a semiconductor layer to block the diffusion of oxidant;

FIGS. 9A-9B are schematic block diagrams illustrating an approach to fabricating a SOI structure where a porous material layer consists of two separate films;

FIGS. 10A-10D are schematic block diagrams illustrating SGOI and SSOI fabrication in accordance with the invention; and

FIGS. 11A-11B are schematic block diagrams illustrating SGOI fabrication using a strained-Si layer.

### DETAILED DESCRIPTION OF THE INVENTION

The invention provides a technique of semiconductor-on-insulator substrate fabrication, and more specifically, a technique of producing a semiconductor substrate of silicon-on-insulator (SOI), relaxed Si₁₋ₓGeₓ-on-insulator (SGOI), strained-Si-on-insulator (SSOI) substrate for various electronics or optoelectronics applications. The invention also provides a semiconductor-on-porous-semiconductor structure and a semiconductor-on-insulator structure with additional porous-semiconductor film. One advantageous feature of the invention is that it does not involve costly process such as high dose ion (oxygen or hydrogen) implantation and wafer bonding. The invention also produces semiconductor-on-insulator substrates with improved semiconductor overlayer thickness uniformity and the semiconductor film can be made to be very thin. The semiconductor overlayer thickness and uniformity can be defined by epitaxial growth.

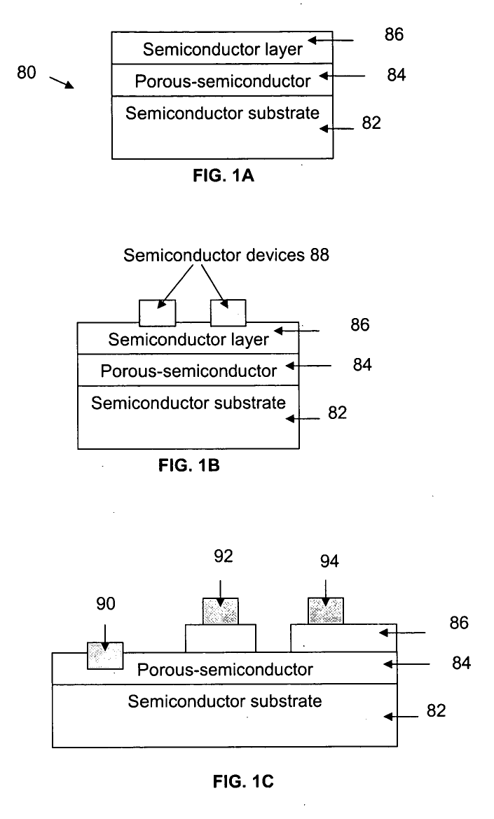

FIG. 1A is schematic block diagram illustrating a Si-on-porous structure 80. The structure 80 includes a substrate 82 and a single crystalline semiconductor layer 86, such as a single crystal silicon film, that is formed on a porous Si layer 84. FIG. 1B shows semiconductor devices 88, such as a RF device 92, a light emitting device 90 and a digital device 94, being formed on the Si-on-porous structure 80. Similar to the conventional MOSFET devices on a SOI structure, MOSFET devices on a Si-on-porous structure 80 have reduced source/drain junction capacitance, since the buried porous Si layer 84 reduces the capacitance significantly due to the exist of the many pores in the layer 84, analogous to the function of buried-oxide in a conventional SOI structure. The pores also prevent easy formation of parasitic current path in porous layer 84 between source and drain. Therefore, the Si-on-porous structure 80 can be used to fabricate advanced devices similar those formed on a conventional SOI structure, and gain similar advantages as the device on conventional SOI substrate. Moreover, such a structure suffers less floating-body effect as that in a conventional SOI structure, since the Si film is connected to the Si substrate 82 via the porous Si layer 84.

The presence of the porous Si layer 84 on the Si-on-porous structure 80 also represents a further opportunity to integrate different devices 88 into the system. Porous Si has very different properties from the bulk Si material. For example its resistivity can be very high, for example 10⁶ ohm-cm, which are many orders of magnitude higher than the bulk Si substrate. Therefore, the porous layer 84 can be utilized to isolate radio frequency (RF) devices 92 from the digital devices 94, as shown in FIG. 1C, because the high resistivity porous Si layer 84 reduces the cross-talk between the devices 92 and device 94 very efficiently.

Another interesting property of porous Si is its significant photoluminescence properties, which can be utilized to produce porous Si light emitting device 90, as shown in FIG. 1C. A window is opened on the single crystalline Si film layer 86 so that a porous Si light emitting diode 90 is fabricated. Such a light emitting device 90 can be used, for example, as a solution to optical interconnection for a digital microprocessor. Furthermore, FIG. 1C illustrates the potential of a Si-on-porous structure 80 being used as an integration platform for different types of devices 90, 92, 94, all within a single monolithic Si substrate 82. This is highly desirable for modern integrated circuit systems.

The application of the above mentioned concept and structure is not limited to Si. Both the porous semiconductor layer 84 and the single crystalline semiconductor 86 can comprise strained-Si, relaxed-SiGe, strained-SiGe, relaxed-Ge, strained-Ge, SiC, GaN, GaAs or the like. Strained-Si, for example, gives high electron and hole mobility, while porous SiGe materials exhibit different properties from porous Si materials.

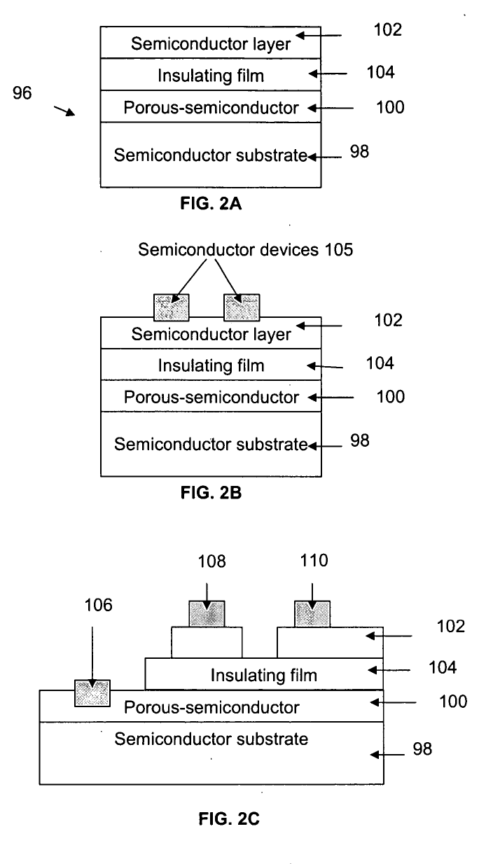

FIGS. 2A-2C illustrate yet another semiconductor-on-insulator-on-porous structure 96. The structure 96 includes a substrate 98 and single crystalline semiconductor layer 102 that is formed on an insulating film 104 that is also formed on a porous-semiconductor layer 100. The insulating film 104 can be either a silicon dioxide layer, a oxidized porous semiconductor layer or other oxide materials, such as epitaxial single-crystalline Zirconium oxide (ZrO₂) layer. FIGS. 2B and FIG. 2C shows various devices 105, 106, 108, 110 being integrated on the structure 96, analogous to those on FIGS. 1B-1C. This insulating layer 104 can be very thin, compared to the porous layer 100. In this structure 96, both the insulating film 104 and the porous layer 100 work together, in a similar way like that in a conventional SOI structure. Therefore, the advantages of SOI devices are kept in this inventive structure 96. Also, the presence of the porous semiconductor layer 100 enables the integration of RF and digital devices 108, 110 and the porous semiconductor light emitting device 106 on the same chip.

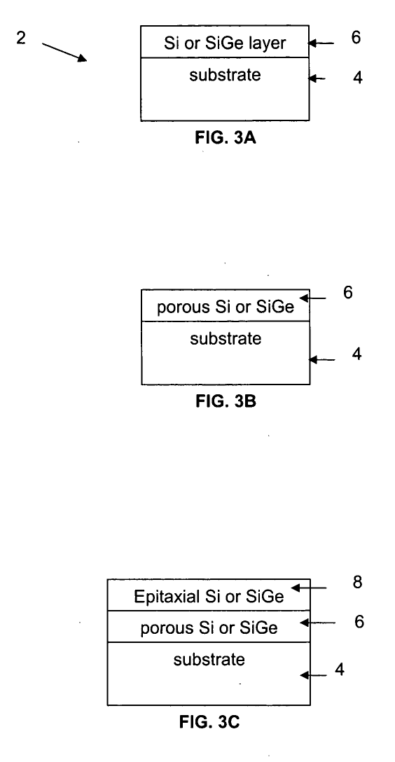

FIGS. 3A-3C illustrates a simple technique to produce a Si-on-porous structure with low fabrication cost and high film uniformity. FIG. 3A shows a single crystal silicon wafer 2 that includes a Si substrate 4 and a surface silicon layer 6, which is then converted into a porous Si layer 6 by anodization, as shown in FIG. 3B. The porous layer 6 can be also formed by other electrochemical processes, such as a stain etch process. A silicon wafer with an expitaxial SiGe surface layer (a strained-SiGe layer) can also be used and the SiGe layer is then converted into porous SiGe layer using the same technique described for forming the porous Si layer. Given the porous Si or SiGe layer 6 is a single crystal material, a high quality Si epitaxial layer 8 can be grown on top of the porous layer 6, as shown in FIG. 3C.

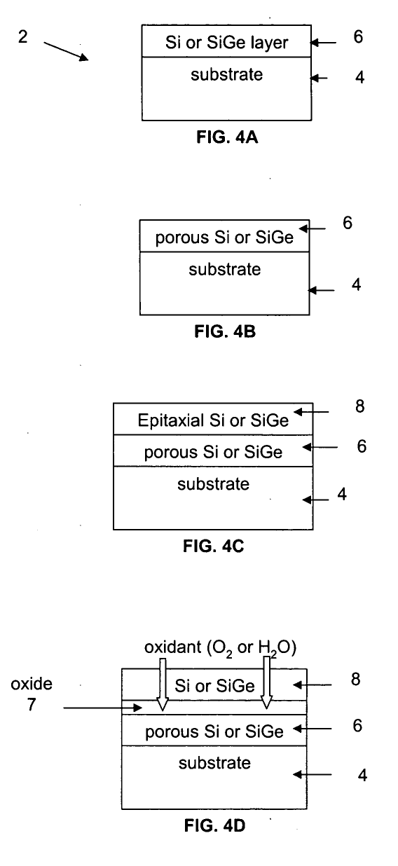

FIGS. 4A-4D illustrates another simple technique to produce a Si-on-insulator-on-porous structure with low fabrication cost and high film uniformity. The first 3 steps shown in FIGS. 4A-4C are exactly the same as those in FIG. 3A-3C. A last step is illustrated in FIG. 4D, where the whole structure is oxidized. During the oxidation, a thin oxide layer 7 is formed between the Si overlayer 8 and the buried porous-semiconductor layer 6, since the oxidant (O₂ or H₂O) can diffuse through the thin Si overlayer 8 and react at the interface. This is analogous to the well-know phenomenon in the prior art called ITOX (internal thermal oxidization).

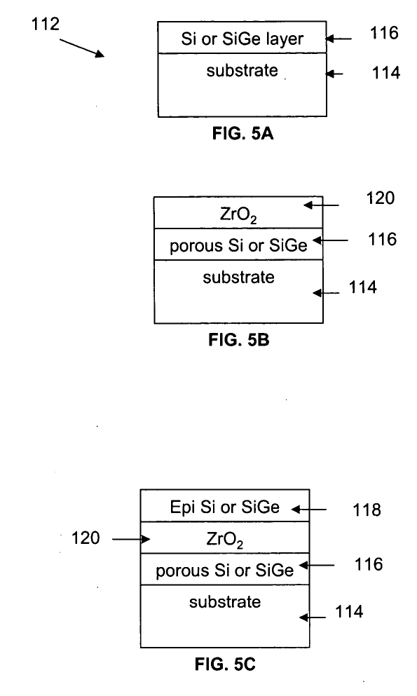

FIGS. 5A-5C show yet another simple technique to produce a Si-on-porous structure 112 with a ZrO₂ layer 120. FIG. 5A shows a Si layer 116 that is formed on a substrate 114, and then converted into a porous Si layer 116, as shown in FIG. 5B. A thin single crystalline oxide layer 120, such as a ZrO₂ layer, is deposited on the porous layer 116, as show in FIG. 5B. Given that the ZrO₂ layer 120 is a single crystal material, a high quality Si epitaxial layer 118 can be grown on top, as shown in FIG. 5C, resulting in a Si-on-insulator-on-porous structure 122. Note in other embodiments the Si layer 116 can also be a SiGe layer.

Note wafer-bonding and a high dose ion implantation are not used to form the various Si-on-porous Si-on-insulator-on-porous structures described herein, and thus the fabrication cost is low. Also, the top semiconductor layers 8, 86, 102, and 118 can be defined by epitaxial growth, which yields excellent film thickness uniformity, and these films can be designed to be very thin.

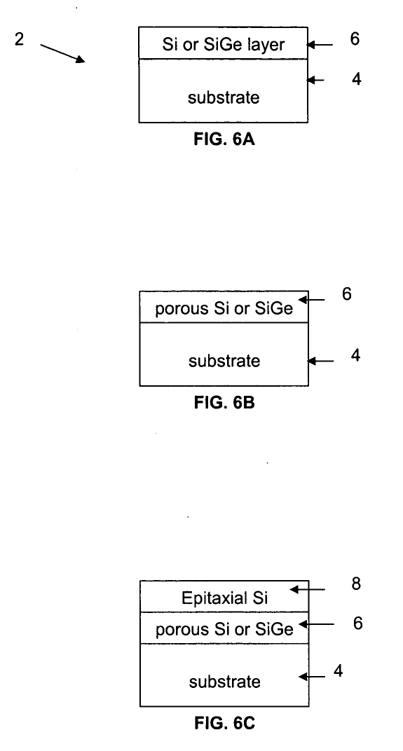

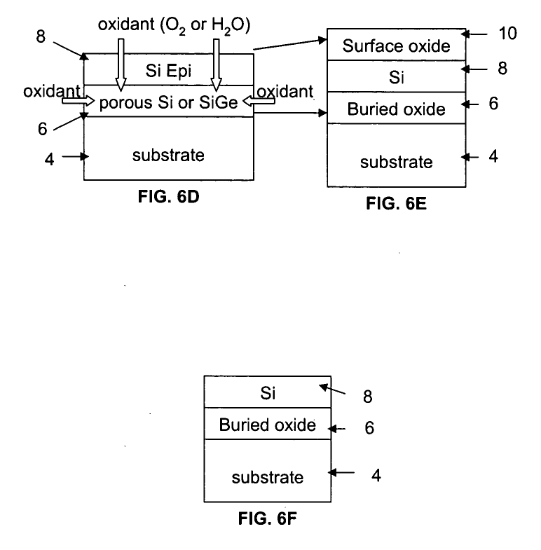

FIG. 6A-6F are schematic block diagrams illustrating an approach to fabricate a SOI structure. The first 3 steps shown in FIGS. 6A-6C are the same as those in FIGS. 3A-3C. The substrate is then oxidized in an oxygen or water vapor ambient, as shown in FIG. 6D. While the oxidant (O₂ or H₂O) reacts with the Si epitaxial layer 8 to form a surface oxide layer 10, as shown in FIG. 6E, the oxidant is also diffused through the Si epitaxial layer 8 and reacts with Si or SiGe in the porous layer 6. As shown in FIG. 6D, this is done to convert the porous layer 6 into a buried oxide layer (BOX). Oxidant is also diffused from the side of the wafer 2 to enhance the oxidation of the porous layer 6.

The oxidation rate of the porous material is much faster than the bulk material because of two reasons: (1) the diffusion of oxidant through the empty space (pores) in the porous material are very fast, and (2) the oxidation rate of porous material are much faster than the bulk material due to the very high surface/volume ratio. If the porous layer is porous SiGe, it enhances oxidation rate even further compared to porous Si. That is, the oxidation rate of SiGe is much faster than Si due to the different chemical reaction rate constant k, for SiGe and for Si. For example, it is found the oxidation of bulk Si_{0.7}Ge_{0.3} is about 50 times faster than Si. As a result of this fast oxidation of the porous materials, the entire porous layer can be oxidized quickly. Therefore, the invention provides a less-costly technique to produce SOI substrate compared to the other prior-art techniques, which involve costly processes, such as high dose ion implantation or wafer bonding. The uniformity of the film thickness is also enhanced as it is defined by epitaxial growth. After the oxidation, the top oxide layer 10 can be removed as shown in FIG. 6F. The technique described herein can also be applied to produce other semiconductor material on insulator structures, besides Si film.

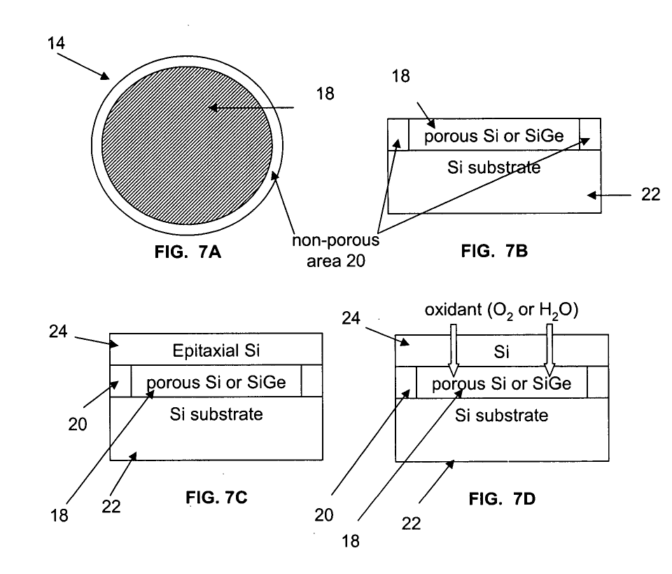

In a modified approach, the diffusion of oxidant from the side of a wafer 14 may be blocked. FIG. 7A shows a top view of the wafer 14 where the very edge 20 of the wafer can be excluded from converting into a porous area 18. This can be easily done by those skilled in the art. For example, the edge region 20 and center region 18 have different types of doping or different doping levels, such that only center region 18 is converted to porous during the consequent anodization process for porous formation, since the anodization process is sensitive to the doping type and doping level. FIG. 7B is a cross-sectional view of the wafer 14 after porous formation. After the anodization step, a Si layer 24 is deposited over both the non-porous area 20 and the porous Si area 18, as shown in FIG. 7C. During the oxidation step the oxidant is only diffused through the top Si layer 24, as shown in FIG. 7D. The diffusion from the side is blocked by the edge exclusion, resulting in uniform oxidant diffusion across the wafer 14 and good film uniformity in the final SOI substrate.

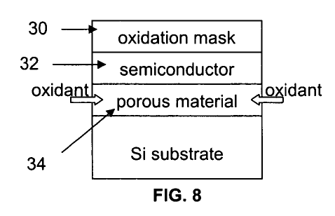

The inventive technique can also allow the diffusion of oxidant through the top semiconductor layer be blocked, so that the diffusion is only through the side of the wafer. For example an oxidation mask layer 30 can be added on the top semiconductor layer 32 to block the diffusion of oxidant from top and to prevent the oxidation at the top semiconductor surface 32, as shown in FIG. 8. Such an oxidation mask layer 30 can be a deposited silicon nitride layer. As a result, the oxidation and diffusion at top semiconductor 32 are prevented. Oxidant is diffused from side to oxidize the porous layer 34. Due to the very fast oxidation rate and diffusion rate in the porous structure, the entire porous layer 34 can be oxidized. The advantage of this approach is that the top semiconductor layer 32 is not consumed during the process.

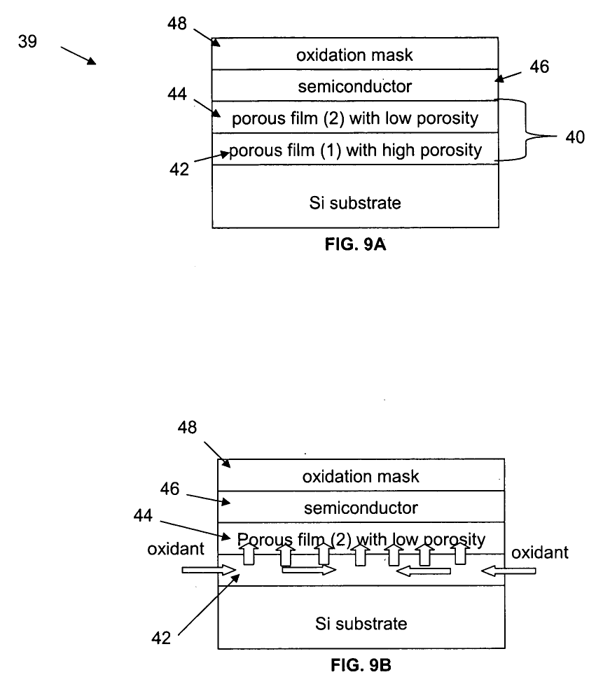

FIGS. 9A-9B are schematic block diagrams illustrating an approach to fabricating a SOI structure 39. In this approach, the porous material layer 40 consists of two separate films 42, 44. The bottom porous film 42 has high porosity and larger pores, (for example porosity larger than 60%). The top porous film 44 has low porosity. These two porous film structures 42, 44 are formed by adjusting the anodization current for each film during the anodization process. After forming the two porous films 42, 44, a semiconductor layer 46 is deposited on the surface and then an oxidation mask layer 48 is deposited as shown in FIG. 9A. During the next step of oxidation or nitridation process, the porous film 42 acts as an oxidant diffusion channel, due to its large pores, as shown in FIG. 9B. This facilitates the oxidant diffusion into the entire wafer 39, and thus the porous film 42 is oxidized more rapidly. The oxidants can further diffuse to the other porous layer 44 to facilitate oxidation of layer 44. The position of the two porous layers 42 and 44 can be reversed.

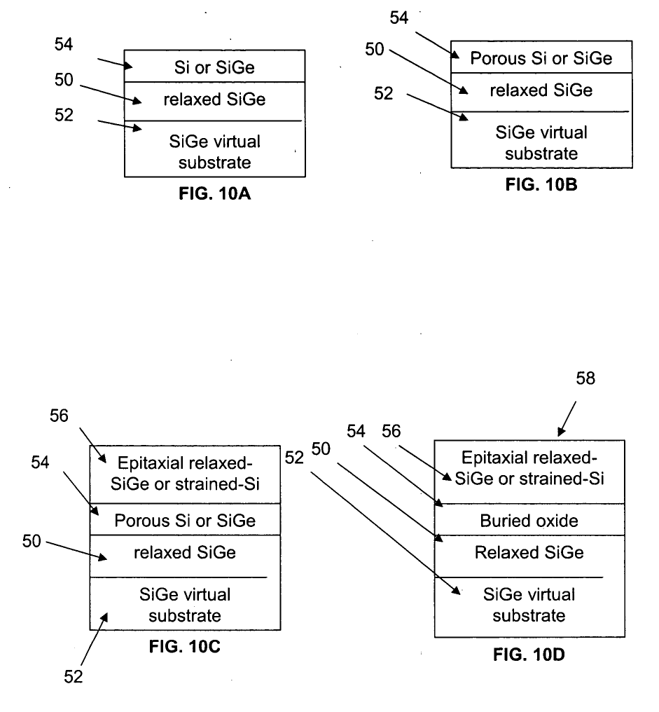

FIGS. 10A-10D are schematic block diagrams illustrating SGOI or SSOI fabrication in accordance with the invention. FIG. 10A shows a relaxed SiGe layer 50 that is provided on a substrate 52. The substrate 52 can be a conventional SiGe virtual substrate, grown by the SiGe grade epi growth technique known in the art. On this relaxed SiGe layer 50, a strained-Si or relaxed-SiGe layer 54 is provided, as shown in FIG. 10A. This surface layer 54 is later converted into porous layer, as shown in FIG. 10B. A strained-Si or relaxed-SiGe layer 56 is then grown on the top of porous layer 54, as shown in FIG. 10C. An oxidation or nitridation step is conducted to convert the porous layer 54 into an insulator layer, resulting in a SGOI or a SSOI substrate 58, as shown in FIG. 10D.

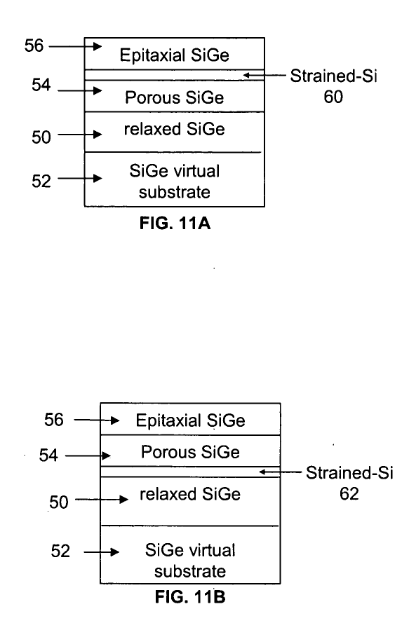

In a modified approach to the technique of FIGS. 10A-10D, a strained-Si layer 60 can be presented between the porous SiGe 54 and top SiGe layer 56, as shown in FIG. 11A. Such a strained-Si layer 60 can be used to define a better SiGe/BOX interface (oxidation rate are different for two materials) and be used to improve the semiconductor/oxide interface (Si/BOX instead of SiGe/BOX). Similarly a strained-Si layer 62 can also be presented between porous SiGe 54 and SiGe buffer layer 56, as shown in FIG. 11B.

After fabricating the SOI/SGOI/SSOI substrate by converting porous material layer into BOX layer using approaches described above according to the invention, additional approaches may be used to enhance the material quality.

For example, an additional anneal step may be conducted to densify the BOX layer, which improved the quality of the BOX. An additional oxidation step may also be conducted at this point. This additional oxidation step will oxide the non-porous semiconductor top layer at the semiconductor/BOX interface, which forms a layer of conventional thermal oxide from bulk material. Therefore, this step will replace the semiconductor/porous-oxide interface with semiconductor/thermal-oxide interface, and thus the interface quality is improved.

Although the present invention has been shown and described with respect to several preferred embodiments thereof, various changes, omissions and additions to the form and detail thereof, may be made therein, without departing from the spirit and scope of the invention.

What is claimed is:

1. A semiconductor on porous structure comprising:
a semiconductor substrate;
a first semiconductor layer that is formed on said substrate, said first semiconductor layer being converted into a porous semiconductor layer, and a second semiconductor layer that is formed on said first semiconductor layer.

2. The semiconductor on porous structure of claim 1 further comprising a semiconductor device that is fabricated on said second semiconductor layer.

3. The semiconductor on porous structure of claim 2, wherein said semiconductor device comprises one or more of the following devices: a digital device, an analog device, a radio frequency device, an optoelectronic device.

4. The semiconductor on porous structure of claim 1 further comprising an opening on said second semiconductor layer that is used to make optical devices such as light emitting devices on said porous layer.

5. The semiconductor on porous structure of claim 1, wherein said semiconductor substrate comprises either a Si substrate, a SiGe substrate, a SiGe virtual substrate, a SiC substrate, or a Ge substrate.

6. The semiconductor on porous structure of claim 1, wherein said first semiconductor layer comprises one or more of the following materials: Si, strained-Si, relaxed-SiGe, a strained-SiGe, relaxed-SiC, strained-SiC, relaxed-Ge, strained-Ge, GaN, GaAs or other III-V materials.

7. The semiconductor on porous structure of claim 1, wherein said second semiconductor layer comprises one or more of the following materials: Si, strained-Si, relaxed-SiGe, a strained-SiGe, relaxed-SiC, strained-SiC, relaxed-Ge, strained-Ge, GaN, GaAs or other III-V materials.

8. A semiconductor structure comprising:
a semiconductor substrate;
a porous semiconductor layer that is formed on said substrate;
an insulating film that is formed on said porous layer; and
a second semiconductor layer that is formed on said insulating film.

9. The semiconductor structure of claim 8, wherein said insulating film comprises at least one of the following materials: a silicon oxide layer, an oxidized porous layer, or an epitaxial single-crystalline oxide layer such as an ZrO₂ film.

10. The semiconductor on porous structure of claim 8 further comprising a semiconductor device that is fabricated on said second semiconductor layer.

11. The semiconductor on porous structure of claim 10, wherein said semiconductor device comprises one or more of the following devices: a digital device, an analog device, a radio frequency device, an optoelectronic device.

12. The semiconductor on porous structure of claim 8, further comprising an opening on said second semiconductor layer that is used to make optical devices such as light emitting devices on said porous layer.

13. The semiconductor on porous structure of claim 8, wherein said semiconductor substrate comprises either a Si substrate, a SiGe substrate, a SiGe virtual substrate, a SiC substrate, or a Ge substrate.

14. The semiconductor on porous structure of claim 8, wherein said first semiconductor layer comprises one or more of the following materials: Si, strained-Si, relaxed-SiGe, a strained-SiGe, relaxed-SiC, strained-SiC, relaxed-Ge, strained-Ge, GaN, GaAs or other III-V materials.

15. The semiconductor on porous structure of claim 8, wherein said second semiconductor layer comprises one or more of the following materials: Si, strained-Si, relaxed-SiGe, a strained-SiGe, relaxed-SiC, strained-SiC, relaxed-Ge, strained-Ge, GaN, GaAs or other III-V materials.

16. A semiconductor structure comprising:
a substrate; and
a first semiconductor layer that is formed on the substrate being converted into a porous layer, wherein said porous layer is further oxidized or nitridized to form a buried oxide layer.

17. The semiconductor structure of claim 16 further comprising a second semiconductor layer that is formed on said buried oxide layer so that said semiconductor structure is a semiconductor-on-insulator structure.

18. The semiconductor structure of claim 16, wherein said first semiconductor layer comprises at least one of the following layer: a Si layer, a strained-Si layer, a relaxed-SiGe layer, a strained-SiGe layer, a relaxed-SiC layer, a strained-SiC layer, a relaxed-Ge layer, a strained-Ge layer, GaN, GaAs or other III-V materials.

19. The semiconductor structure of claim 16, wherein said substrate comprises either a Si substrate, a SiGe virtual substrate, SiC substrate, or a Ge substrate, GaAs or other III-V materials.

20. The semiconductor structure of claim 16, wherein said semiconductor layer forms two porous layers having varying porosity, wherein said one of the porous layer having the larger porosity is further oxidized totally to form a buried oxide layer.

21. The semiconductor structure of claim 17, wherein said second semiconductor layer comprises either a relaxed-Si layer, a strained-Si layer, a relaxed-SiGe layer, a strained-SiGe layer, a relaxed-Ge layer, a strained-Ge layer, GaN, GaAs or other Ill-V materials.

22. The semiconductor structure of claim 17, wherein said second semiconductor layer comprises a relaxed-SiGe layer and a strained-Si layer, said strained-Si layer being formed between said relaxed-SiGe layer and said first semiconductor layer.

23. The semiconductor structure of claim 17 further comprising a strained-Si layer formed between said first semiconductor layer and said substrate.

24. The semiconductor structure of claim 17 further comprising a semiconductor device, being fabricated on said second semiconductor layer.

25. The semiconductor structure of claim 17, wherein said semiconductor device comprises one or more of the following devices: a digital device, an analog device, a radio frequency device, an optoelectronic device.

26. A method of forming a semiconductor structure comprising:
providing a substrate;
forming a first semiconductor layer on said substrate;
converting said first semiconductor layer into a porous layer; and
oxidizing or nitridizing said porous layer to form a buried insulator layer.

27. The method of claim 26 further comprising forming a second semiconductor layer on said porous layer before said step of oxidizing or nitridizing said porous layer to form a buried oxide layer, so that said semiconductor structure is a semiconductor-on-insulator structure.

28. The method of claim 26, wherein said first semiconductor layer comprises at least one of the following layer: a Si layer, a strained-Si layer, a relaxed-SiGe layer, a strained-SiGe layer, a relaxed-SiC layer, a strained-SiC layer, a relaxed-Ge layer, a strained-Ge layer, GaN, GaAs or other III-V material.

29. The method of claim 26, wherein said substrate comprises either a Si substrate, a SiGe virtual substrate, SiC substrate, a Ge substrate, a GaN substrate, a GaAs or other III-V substrate.

30. The method of claim 26, wherein said first semiconductor layer forms two porous layers having varying porosity, wherein said one of the porous layer having the larger porosity is further oxidized or nitridized totally to form a buried insulator layer.

31. The method of claim 27, wherein said second semiconductor layer comprises either a relaxed-Si layer, a strained-Si layer, a relaxed-SiGe layer, a strained-SiGe layer, a relaxed-Ge layer, a strained-Ge layer, GaN, GaAs or other III-V material.

32. The method of claim 27, wherein said second semiconductor layer comprises a relaxed-SiGe layer and a strained-Si layer, said strained-Si layer being formed between said relaxed-SiGe layer and said first semiconductor layer.

33. The method of claim 27 further comprising a strained-Si layer formed between said first semiconductor layer and said substrate.

34. The method of claim 27 further comprising a semiconductor device, being fabricated on said second semiconductor layer.

35. The method of claim 27, wherein said semiconductor device comprises one or more of the following devices: a digital device, an analog device, a radio frequency device, an optoelectronic device.

36. A method of forming a semiconductor structure comprising:
providing a semiconductor substrate;
forming a porous semiconductor layer on said substrate;
forming an insulating film on said porous layer; and
forming a second semiconductor layer on said insulating film.

37. The method of claim 36, wherein said insulating film comprises at least one of the following materials: a thermal oxide layer, a oxidized porous layer, or an epitaxial single-crystalline oxide layer such as an ZrO₂ film.

38. The method of claim 36 further comprising fabricating a semiconductor device on said second semiconductor layer.

39. The method of claim 38, wherein said semiconductor device comprises one or more of the following devices: a digital device, an analog device, a radio frequency device, an optoelectronic device.

40. The method of claim 36, further comprising using an opening on said second semiconductor layer to make optical devices such as light emitting devices.

41. The method of claim 36, wherein said semiconductor substrate comprises either a Si substrate, a SiGe substrate, a SiGe virtual substrate, a SiC substrate, a Ge substrate, a GaN, GaAs or other III-V substrate.

42. The method of claim 36, wherein said first semiconductor layer comprises one or more of the following materials: Si, strained-Si, relaxed-SiGe, a strained-SiGe, relaxed-SiC, strained-SiC, relaxed-Ge, strained-Ge, GaN, GaAs or other III-V materials.

43. The method of claim 36, wherein said second semiconductor layer comprises one or more of the following materials: Si, strained-Si, relaxed-SiGe, a strained-SiGe, relaxed-SiC, strained-SiC, relaxed-Ge, strained-Ge, GaN, GaAs or other III-V materials.

44. A method of forming a semiconductor on porous structure comprising:
providing a semiconductor substrate;
forming a first semiconductor layer on said substrate;
converting said first semiconductor layer into a porous semiconductor layer, and forming a second semiconductor layer on said first semiconductor layer.

45. The method of claim 44 further comprising fabricating a semiconductor device on said second semiconductor layer.

46. The method structure of claim 45, wherein said semiconductor device comprises one or more of the following devices: a digital device, analog device, a radio frequency device, an optoelectronic device.

47. The method of claim 44, further comprising an opening on said second semiconductor layer that is used to make optical devices such as light emitting devices.

48. The method of claim 44, wherein said semiconductor substrate comprises either a Si substrate, a SiGe substrate, a SiGe virtual substrate, a SiC substrate, a Ge substrate, GaN substrate, a GaAs or other Ill-V substrate.

49. The method of claim 44, wherein said first semiconductor layer comprises one or more of the following materials: Si, strained-Si, relaxed-SiGe, a strained-SiGe, relaxed-SiC, strained-SiC, relaxed-Ge, strained-Ge, GaN, GaAs or other III-V materials.

50. The method of claim 44, wherein said second semiconductor layer comprises one or more of the following materials: Si, strained-Si, relaxed-SiGe, a strained-SiGe, relaxed-SiC, strained-SiC, relaxed-Ge, strained-Ge, GaN, GaAs or other Ill-V materials.

51. The method of claim 44 further comprising oxidizing or nitridating after said step of forming a second semiconductor layer, so that an additional thin insulator layer form between said second semiconductor layer and said porous layer.
